(19) United States
(12) Patent Application Publication
(10) Pub. No.: US 2006/0246360 A1
(43) Pub. Date: Nov. 2, 2006

(54) Flat panel display device with thin film transistors and method of making thereof

(76) Inventor: Eui-Hoon Hwang, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/378,571

(22) Filed: Mar. 17, 2006

(30) Foreign Application Priority Data
Mar. 18, 2005 (KR) 10-2005-0022813

(51) Int. Cl. G03F 1/00

(52) U.S. Cl. 430/5

(57) ABSTRACT

A thin film transistor, a flat panel display device, and a method of fabricating thereof are disclosed. The flat panel display device includes a substrate, a display array formed over the substrate, and a transistor formed over the substrate. The transistor has a semiconductor layer. The flat panel display device also includes a light-shielding layer interposed between the substrate and the semiconductor layer. The light-shielding layer is configured to shield at least a portion of the semiconductor layer so as to substantially prevent ambient light from reaching the semiconductor layer via the substrate. The light-shielding layer prevents light-induced off-current and may serve as a mask in patterning a photoresist for doping impurities into the semiconductor layer.

### CROSS-REFERENCE TO RELATED APPLICATIONS

This application claims priority to and the benefit of Korean Patent Application No. 2005-22813, filed Mar. 18, 2005, which is incorporated herein by reference in its entirety.

### BACKGROUND OF THE INVENTION

1. Field of the Invention

The present invention relates to flat panel display devices, and more particularly to a light-shielding layer for a thin film transistor in active matrix display devices.

2. Description of the Related Technology

Flat panel display devices are classified into a passive matrix type and an active matrix type. An active matrix flat panel display device has advantages compared to a passive matrix flat panel display device in that it consumes less power and is easier to provide a large-sized display with high resolution.

In the active matrix flat panel display device, unit pixel regions are arranged in a matrix form defined by a plurality of scan lines and a plurality of data lines. Each unit pixel region includes at least one thin film transistor. The thin film transistor has a semiconductor layer pattern having a channel region, a gate electrode, and source and drain electrodes. The channel region may be exposed to ambient light. The light reaching the channel region may create electron-hole pairs in the channel region, and the electrons and holes may produce light-induced off-current. Such light-induced off-current may adversely affect the image quality of the flat panel display device.

### SUMMARY OF CERTAIN INVENTIVE ASPECTS

One aspect of the invention provides a flat panel display device, comprising: a substrate having a surface; a display array formed over the surface, the display array comprising a plurality of pixels; a transistor formed over the surface and comprising a gate, a semiconductor layer, and a gate insulating layer interposed between the gate and the semiconductor layer, the semiconductor layer comprising a source, a drain, a channel, a first lightly-doped region located between the source and the channel, and a second lightly-doped region located between the drain and the channel; and means for selectively blocking light from reaching a photoresist layer so as to form a mask for use in doping the source and drain regions of the semiconductor layer during fabrication of the transistor, the means being interposed between the surface and the semiconductor layer.

In the device, the source and the first lightly-doped region may form a first boundary therebetween by a substantially discrete differential in the concentration of a dopant at both sides of the first boundary. The drain and the second lightly-doped region may form a second boundary therebetween by a substantially discrete differential in the concentration of the dopant at both sides of the second boundary. The location and size of the means may determine the location of the first and second boundaries.

The channel may have a channel length in a first axis and a channel width in a second axis perpendicular to the first axis, the first and second axes being substantially parallel to the surface, and the first and second boundaries may extend in the second axis. The means may comprise a light-shielding layer having a first edge and second edge, both extending generally in the second axis, and the first edge may underlie the first boundary and the second edge may underlie the second boundary.

The light-shielding layer may have the width in the second axis, and the width of the light-shielding layer may be about equal to or greater than the channel width. The first edge may substantially directly underlie the first boundary, and the second edge may substantially directly underlie the second boundary. The first edge may underlie the source, and the second edge may underlie the drain. The first edge may underlie the first lightly-doped region, and the second edge may underlie the second lightly-doped region. The light-shielding layer may have the length in the first axis, and the length of the light-shielding layer may be substantially equal to a total length of the channel and the first and second lightly-doped regions.

The gate may have a first gate edge and second gate edge, both extending generally in the second axis, and the first gate edge may overlie a boundary between the first lightly-doped region and the channel. The second gate edge may overlie a boundary between the second lightly-doped region and the channel. The first and second boundaries may further extend in a general direction perpendicular to the surface with or without a slight bending along the first axis. The transistor may be located between the substrate and the display array. Each of the plurality of pixels may comprise an organic light emitting diode. The light-shielding layer may comprise a metal. The device may further comprise a buffer layer interposed between the light-shielding layer and the semiconductor layer, wherein the buffer layer blocks migration of materials between the light-shielding layer and the semiconductor layer.

Another aspect of the invention provides a method of making a flat panel display device. The method comprises: providing a transparent substrate; forming a light-shielding layer over the substrate; forming a semiconductor layer over the light-shielding layer; forming a photoresist layer over the semiconductor layer; projecting light in a direction such that the light passes through the substrate before reaching the photoresist layer, wherein the light-shielding layer blocks the light, and wherein the light selectively illuminates at least one portion of the photoresist layer; and removing the at least one illuminated portion of the photoresist layer while leaving at least one non-illuminated portion

In the method, removing the at least one illuminated portion may comprise forming a doping mask over the semiconductor layer while exposing at least one portion of the semiconductor layer. The method may further comprise selectively doping with a dopant the at least one portion of the semiconductor layer using the doping mask, thereby forming a source and a drain in the semiconductor layer. The method may further comprise, prior to forming the semiconductor layer, forming a buffer layer over the light-shielding layer so as to prevent migration of materials between the light-shielding layer and the semiconductor layer.

The method may further comprise, prior to forming the photoresist layer, forming a gate insulating layer over the semiconductor layer. The method may further comprise: removing the photoresist layer; forming a gate electrode over the gate insulating layer; and selectively doping with a dopant one or more portions of the semiconductor layer using the gate electrode as a mask, thereby creating one or more lightly-doped drain regions in the semiconductor layer.

The one or more lightly-doped drain regions may comprise a first lightly-doped drain region and a second lightly-doped drain region, and the semiconductor layer may comprise a channel between the first and second lightly-doped regions, the channel having a channel width and a channel length.

The light-shielding layer may have the length in the direction of the channel length, and the length of the light-shielding layer may be substantially equal to the total length of the channel and the first and second lightly-doped regions. The semiconductor layer may comprise a channel of a transistor, the channel comprising a channel width and a channel length, and the light-shielding layer may have the width in the direction of the channel width. The width of the light-shielding layer may be about equal to or greater than the channel width.

Another aspect of the invention provides a flat panel display device made by the method described above.

Further aspect of the invention provides a thin film transistor capable of preventing light-induced off-current from occurring and a method of fabricating the same. Another aspect of the invention provides a flat panel display device having improved image quality and a method of fabricating the same. Yet another aspect of the invention provides a method of fabricating a thin film transistor and a flat panel display device, which are capable of carrying out impurity doping using a light-shielding layer as a mask without an additional mask.

Another aspect of the invention provides a thin film transistor and a method of fabricating the same. The thin film transistor includes: a substrate; a light-shielding layer formed on the substrate; a buffer layer formed on an entire surface of a substrate including the light-shielding layer; a semiconductor layer pattern including source and drain regions, a channel region, and a lightly doped drain (LDD) region formed on the buffer layer; a gate insulating layer formed on an entire surface of the buffer layer including the semiconductor layer pattern; and a gate electrode formed on the gate insulating layer so as to correspond to the channel region of the semiconductor layer pattern. In this case, the light-shielding layer corresponds to the channel region and the LDD region of the semiconductor layer pattern, and the width of the light-shielding layer is equal to or greater than widths of the channel region and the LDD region of the semiconductor layer pattern.

The method includes: preparing a substrate; forming a light-shielding layer on the substrate; forming a buffer layer on an entire surface of the substrate including the light-shielding layer; forming and patterning a semiconductor layer on the buffer layer and forming a semiconductor layer pattern; forming a gate insulating layer on an entire surface of the buffer layer including the semiconductor layer pattern; forming a photoresist layer on the gate insulating layer, carrying out back exposure using the light-shielding layer as a mask and forming a photoresist pattern; doping a high concentration impurity in the semiconductor layer pattern; removing the photoresist pattern, and forming a gate electrode having the length smaller than the light-shielding layer on the gate insulating layer; and doping a low concentration impurity in the semiconductor layer pattern. The semiconductor layer may include a transistor channel having a channel width and a channel length, and the light-shielding layer has a width in the direction of the channel width and a length in the direction of the channel length. In this case, the width of the light-shielding layer is equal to or greater than the width of the semiconductor layer pattern, and the length of the light-shielding layer is greater than the length of a channel region formed in the semiconductor layer pattern and smaller than the length of the semiconductor layer pattern.

The method may further include: forming an interlayer insulating layer on an entire surface of the substrate including the gate electrode; and forming source and drain electrodes on the interlayer insulating layer, and coupling the source and drain electrodes to source and drain regions via a contact hole formed on the gate insulating layer and the interlayer insulating layer. The light-shielding layer may be formed by an etching process, and, it is not electrically connected to an electrode. The thin film transistor may be an N-type thin film transistor.

Another aspect of the invention provides a thin film transistor and a method of fabricating the same. The thin film transistor includes: a substrate including a circuit region where a first conductive type thin film transistor is to be formed and a pixel region where a second conductive type thin film transistor is to be formed; a first light-shielding layer formed on the circuit region and a second light-shielding layer formed on the pixel region in the substrate; a buffer layer formed on an entire surface of the substrate including the first and second light-shielding layers; a first semiconductor layer pattern including source and drain regions, a channel region, and a lightly doped drain (LDD) region, and a second semiconductor layer pattern including source and drain regions and a channel region, formed on the buffer layer; a gate insulating layer formed on an entire surface of the buffer layer including the first and second semiconductor layer patterns; and first and second gate electrodes formed on the gate insulating layer so as to correspond to the channel regions of the first and second semiconductor layer patterns, respectively. In this case, the first light-shielding layer corresponds to the channel region and the LDD region of the first semiconductor layer pattern, and the width of the first light-shielding layer is equal to or greater than widths of the channel region and the LDD region of the first semiconductor layer pattern, and width and length of the second light-shielding layer are equal to or greater than the width and length of the second semiconductor layer pattern. The method includes: preparing a substrate including a circuit region where a first conductive type thin film transistor is to be formed and a pixel region where a second conductive type thin film transistor is to be formed; forming a first light-shielding layer on the circuit region and a second light-shielding layer on the pixel region in the substrate, respectively; forming a buffer layer on an entire surface of the substrate including the first and second light-shielding layers; forming and patterning a semiconductor layer on the buffer layer and forming first and second semiconductor layer patterns; forming a gate insulating layer on an entire surface of the buffer layer including the first and second semiconductor layer patterns; forming a photoresist layer on the gate insulating layer, carrying out back exposure using the first and second light-shielding layers as masks and forming a photoresist pattern; doping a first high concentration impurity in the first semiconductor layer pattern; removing the photoresist pattern, and forming first and second gate electrodes each having the length smaller than the first light-shielding layer on the gate insulating layer; doping a first low concentration impurity in the first and second semiconductor layer patterns; forming a photoresist pattern on the circuit region including the first gate electrode; and doping a second high concentration impurity in the second semiconductor layer pattern. In this case, widths of the first and second light-shielding layers are equal to or greater than widths of the first and second semiconductor layer patterns, the length of the first light-shielding layer is greater than the length of the channel region formed in the first semiconductor layer pattern and smaller than the length of the first semiconductor layer pattern, and the length of the second light-shielding layer is equal to or greater than the length of the second semiconductor layer pattern.

The method may further include: forming an interlayer insulating layer on an entire surface of the substrate including the first and second gate electrodes; and forming source and drain electrodes on the interlayer insulating layer, and coupling the source and drain electrodes to source and drain regions via a contact hole formed on the gate insulating layer and the interlayer insulating layer.

The first and second light-shielding layers may be formed by an etching process, and may not be electrically connected to an electrode. The first conductive type thin film transistor may be an N-type thin film transistor, and the second conductive type thin film transistor may be a P-type thin film transistor.

Yet another aspect of the invention provides a flat panel display device and a method of fabricating the same. The flat panel display device includes: a substrate including a circuit region where a first conductive type thin film transistor is to be formed and a pixel region where a second conductive type thin film transistor and a capacitor are to be formed; a first light-shielding layer formed on the circuit region and a second light-shielding layer formed on the pixel region in the substrate, respectively; a buffer layer formed on an entire surface of the substrate including the first and second light-shielding layers; a first semiconductor layer pattern including source and drain regions, a channel region, and a lightly doped drain (LDD) region, a second semiconductor layer pattern including source and drain regions and a channel region, and a bottom electrode of the capacitor, formed on the buffer layer; a gate insulating layer formed on an entire surface of the buffer layer including the first and second semiconductor layer patterns and the bottom electrode of the capacitor; first and second gate electrodes, and a top electrode of the capacitor formed on the gate insulating layer above the first and second semiconductor layer patterns and the bottom electrode of the capacitor; an interlayer insulating layer formed on an entire surface of the substrate including the first and second gate electrodes and the top electrode of the capacitor; and source and drain electrodes formed on the interlayer insulating layer, and being coupled to the source and drain regions via a contact hole formed on the gate insulating layer and the interlayer insulating layer. In this case, the first light-shielding layer corresponds to the channel region and the LDD region of the first semiconductor layer pattern, and the width of the first light-shielding layer is equal to or greater than widths of the channel region and the LDD region of the first semiconductor layer pattern, and width and length of the second light-shielding layer are equal to or greater than the width and length of the second semiconductor layer pattern. The bottom electrode of the capacitor may be doped with an N-type impurity.

The method includes: preparing a substrate including a circuit region where a first conductive type thin film transistor is to be formed and a pixel region where a second conductive type thin film transistor and a capacitor are to be formed; forming a first light-shielding layer on the circuit region and a second light-shielding layer on the pixel region in the substrate, respectively; forming a buffer layer on an entire surface of the substrate including the first and second light-shielding layers; forming and patterning a semiconductor layer on the buffer layer and forming a first semiconductor layer pattern, a second semiconductor layer pattern, and a bottom electrode of the capacitor; forming a gate insulating layer on an entire surface of the buffer layer including the first and second semiconductor layer patterns and the bottom electrode of the capacitor; forming a photoresist layer on the gate insulating layer, carrying out back exposure using the first and second light-shielding layers as masks and forming a photoresist pattern; doping a first high concentration impurity in the first semiconductor layer pattern and the bottom electrode of the capacitor; removing the photoresist pattern, and forming first and second gate electrodes each having the length smaller than the first light-shielding layer on the gate insulating layer, and a top electrode corresponding to the bottom electrode of the capacitor; doping a first low concentration impurity in the first and second semiconductor layer patterns; forming a photoresist pattern on the circuit region including the first gate electrode; doping a second high concentration impurity in the second semiconductor layer pattern; removing the photoresist pattern, and forming an interlayer insulating layer on an entire surface of the substrate including the first and second gate electrodes; and forming source and drain electrodes on the inter-insulating layer, and coupling the source and drain electrodes to the source and drain regions via a contact hole formed on the gate insulating layer and the interlayer insulating layer. In this case, widths of the first and second light-shielding layers are equal to or greater than widths of the first and second semiconductor layer patterns, the length of the first light-shielding layer is greater than the length of the channel region formed in the first semiconductor layer pattern and smaller than the length of the first semiconductor layer pattern, and the length of the second light-shielding layer is equal to or greater than the length of the second semiconductor layer pattern.

The method may further include: forming a planarization layer on the interlayer insulating layer including the source and drain electrodes; and forming a pixel electrode on the planarization layer of the pixel region, and coupling the pixel electrode to one electrode of the source and drain electrodes through a via hole formed in the planarization layer. The pixel electrode may be composed of a transparent electrode.

The flat panel display device may be an organic light emitting display device. The light-shielding layer may be formed of a material having a high reflectivity with respect to externally incident lights, for example, a metal. The metal may be one material selected from a group consisting of aluminum, tungsten, titanium, tantalum, chromium, a chromium alloy, molybdenum, and a molybdenum alloy.

### BRIEF DESCRIPTION OF THE DRAWINGS

The above and other features of the present invention will be described in terms of certain exemplary embodiments thereof with reference to the attached drawings.

FIGS. 1A to 1F are cross-sectional views illustrating a thin film transistor and a method of fabricating the same in accordance with a first embodiment of the invention;

FIG. 2 is a plan view illustrating a light-shielding layer and a semiconductor layer pattern in the thin film transistor of the first embodiment;

FIGS. 3A to 3G are cross-sectional views illustrating a thin film transistor and a method of fabricating the same in accordance with a second embodiment of the invention;

FIGS. 4A and 4B are plan views illustrating first and second light-shielding layers and first and second semiconductor layer patterns in the thin film transistor according to the second embodiment of the invention; and

FIGS. 5A to 5H are cross-sectional views illustrating a flat panel display device and a method of fabricating the same in accordance with a third embodiment of the invention.

### DETAILED DESCRIPTION OF CERTAIN INVENTIVE EMBODIMENTS

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. In addition, where a layer is described as being formed on another layer or on a substrate, the layer may be formed on the other layer or on the substrate, or a third layer may be interposed between the layer and the other layer or the substrate. Like numbers refer to like elements in other drawings throughout the specification.

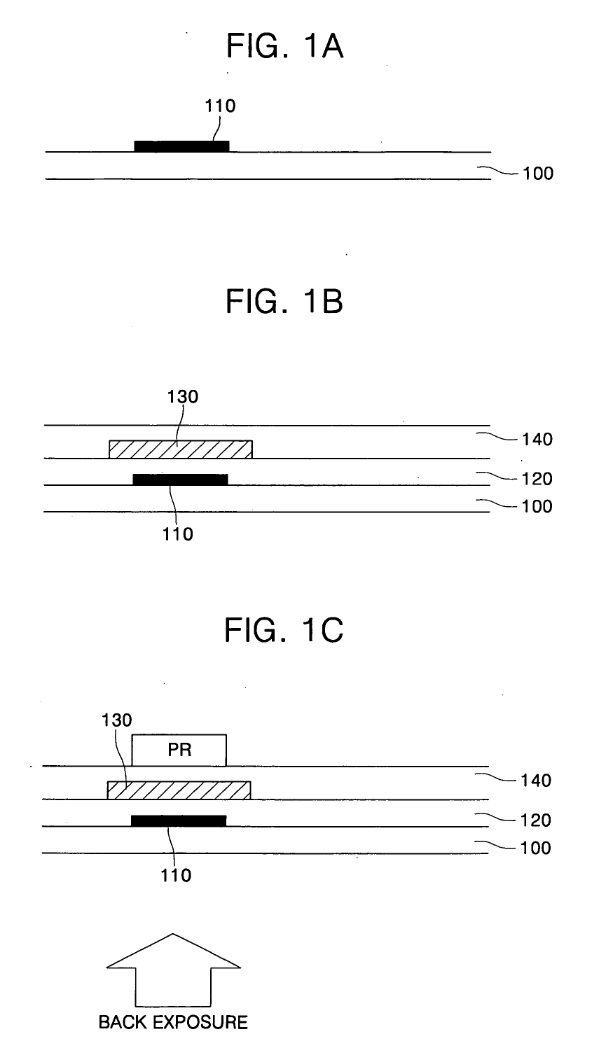

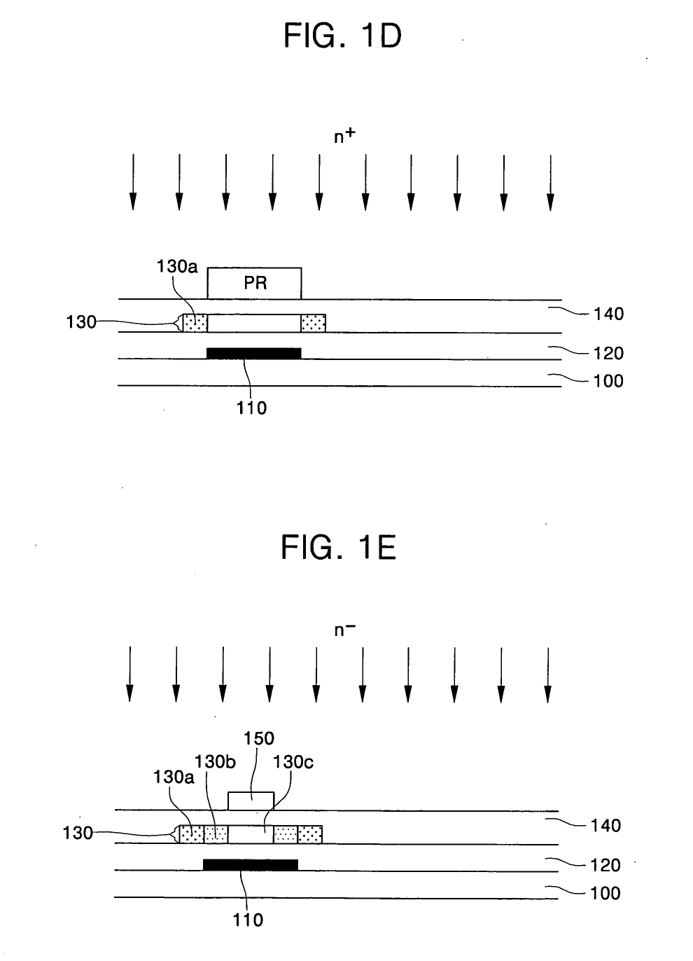

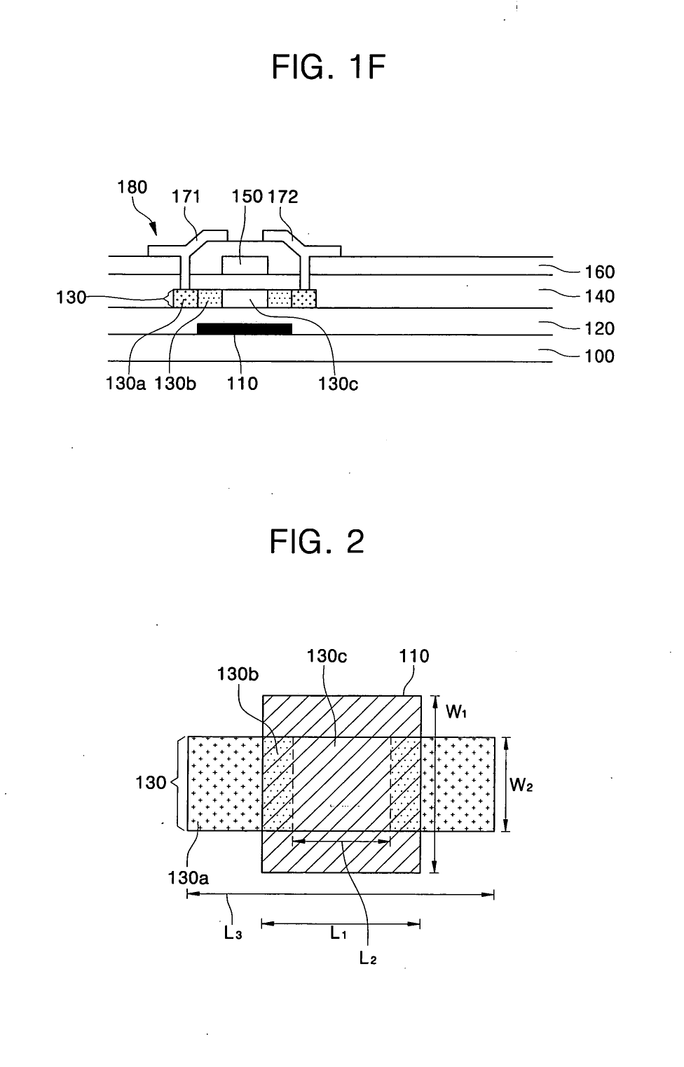

FIGS. 1A to 1F are cross-sectional views illustrating a thin film transistor and a method of fabricating the same in accordance with a first embodiment of the invention. FIG. 2 is a plan view illustrating a light-shielding layer and a semiconductor layer pattern in the thin film transistor according to the first embodiment.

Referring to FIG. 1A, a light-shielding layer 110 is formed on a substrate 100. In one embodiment, the substrate 100 is formed of an insulating material. The substrate 100 may be formed of a glass or transparent plastic material. The light-shielding layer 110 is formed of a material capable of reflecting ambient light incident on the substrate 100. It may be formed of a material having a high reflectivity with respect to the visible light. The material may be formed of a metal. The metal may be one selected from aluminum, tungsten, titanium, tantalum, chromium, a chromium alloy, molybdenum, and a molybdenum alloy. However, the metal is not necessarily limited thereto, and any metal having a thickness capable of reflecting or absorbing light may be used as a material for the light-shielding layer 110. In the alternative, the light-shielding layer 110 is formed of a material that can absorb at least some of the visible light incident on the substrate 100.

The light-shielding layer 110 may be formed by a photolithographic (i.e. exposure) process followed by an etching process. First, a metal is applied onto the substrate 100, and exposure and development are then performed using a mask to form a photoresist pattern. The etching process is then carried out to form the light-shielding layer 110 having a desired pattern. The light-shielding layer 110 may be formed like an island as it is not electrically connected to an electrode as will be described later.

In one embodiment, the light-shielding layer is configured to shield at least a portion of an overlying semiconductor layer as will be further described later. This configuration allows the light-shielding layer 110 to substantially block ambient light from reaching the semiconductor layer via the substrate. The phrase “substantially blocking ambient light,” as used herein, refers to blocking ambient light by a percentage between about 30% and about 100%, including, but not limited to, about 30%, about 35%, about 40%, about 45%, about 50%, about 55%, about 60%, about 65%, about 70%, about 75%, about 80%, about 85%, about 90%, about 95%, and about 100%.

In the illustrated embodiment, the width of the light-shielding layer 110 is greater than the width of a semiconductor layer pattern which will be described later. The “width of the light-shielding layer,” as used herein, refers to the length of the layer in the direction of a channel width of the overlying transistor semiconductor layer. In addition, the length of the light-shielding layer 110 is greater than the length of the channel region to be formed in the semiconductor layer pattern. The length of the light-shielding layer 110, however, is shorter than the length L3 of the semiconductor layer pattern. The “length of the light-shielding layer,” as used herein, refers to the length in the direction of a channel length of the overlying transistor semiconductor layer.

Referring to FIG. 2, the width W1 of the light-shielding layer 110 is greater than the width W2 of the semiconductor layer pattern 130. In addition, the length L1 of the light-shielding layer 110 is greater than the length L2 of the channel region 130c of the semiconductor layer pattern 130 but is smaller than the length L3 of the semiconductor layer pattern 130.

As will be described later, the light-shielding layer 110 is formed so as to define a boundary between source and drain regions 130a and a lightly doped drain (LDD) region 130b. The total length of the LDD regions 130b and the channel region 130c equals to the length L1 of the light-shielding layer 110.

Referring to FIG. 1B, a buffer layer 120 is formed on, for example, the entire surface of the substrate 100 and the light-shielding layer 110. The buffer layer 120 serves to protect a thin film transistor from impurities that may diff use out of the substrate 100.

Subsequently, a semiconductor layer is formed on the buffer layer 120. The semiconductor layer may be formed of an amorphous silicon layer. The semiconductor layer is patterned and then crystallized to form a semiconductor layer pattern 130 formed of a polycrystalline silicon. Alternatively, before the amorphous silicon layer is patterned, the amorphous silicon layer may be crystallized to form a polycrystalline silicon layer, which may be then patterned to form the semiconductor layer pattern 130.

The crystallization may be carried out using a method selected from an excimer laser annealing (ELA) method, a sequential lateral solidification (SLS) method, a metal induced crystallization (MIC) method and a metal induced lateral crystallization (MILC) method. When the crystallization is carried out using the excimer laser annealing method, an excimer laser beam is irradiated onto the semiconductor layer formed of the amorphous silicon layer or the amorphous silicon.

Subsequently, a gate insulating layer 140 is formed on the entire surface of the buffer layer 120 and the semiconductor layer pattern 130. The gate insulating layer 140 may be formed of a silicon oxide layer, a silicon nitride layer, or a composite layer thereof.

Referring to FIG. 1C, a photoresist layer is formed over the gate insulating layer 140. Exposure is then carried out in an upward direction onto a lower surface of the photoresist layer rather than onto an upper surface of the photoresist layer. In other words, back exposure is performed to form a photoresist pattern PR. Development is then carried out to form the photoresist pattern PR. In the illustrated embodiment, an additional masking step for patterning the photoresist pattern PR is not required because the light-shielding layer 110 can serve as a mask. The light-shielding layer 110 not only protects the channel region 130c from externally incident lights but also acts as a mask in patterning the photoresist. Accordingly, the process can be simplified.

Referring to FIG. 1D, a high concentration of impurities is doped in the semiconductor layer pattern 130 using the photoresist pattern as a mask. Accordingly, source and drain regions 130a with a high concentration of impurities are formed in the semiconductor layer pattern 130.

In the illustrated embodiment, N-type impurities are doped, and thus a resulting thin film transistor is an N-type thin film transistor. In other embodiments, P-type impurities may be used as the impurities.

Referring to FIG. 1E, the photoresist pattern is removed and a gate conductive layer is formed on the gate insulating layer 140. The gate conductive layer is then patterned to form a gate electrode 150. The gate electrode 150 crosses the semiconductor layer pattern 130. The gate electrode 150 may be formed of one material selected from chromium (Cr), a Cr alloy, molybdenum (Mo), and a Mo alloy.

Subsequently, a low concentration of impurities is doped in the semiconductor layer pattern 130 using the gate electrode 150 as a mask to form an LDD region 130b. At the same time, a channel region 130c is defined to be interposed between the LDD regions 130b under the gate electrode 150.

By forming the LDD region 130b, a leakage current which might otherwise occur in the channel region 130c can be prevented from occurring. The leakage current tends to occur in an N-type thin film transistor and thus it is advantageous to have the LDD region 130b in an N-type transistor.

In addition, the light-shielding layer 110 protects the channel region 130c from ambient light so as to prevent light-induced off-current. The photoresist pattern for forming the LDD region 130b can be formed using the light-shielding layer 110 as a mask.

In the illustrated embodiment, the total length of the LDD regions 130b and the channel region 130c equals to the length L1 of the light-shielding layer 110. This is consistent with description relating to formation of the light-shielding layer 110 of FIG. 1A.

Referring to FIG. 1F, an interlayer insulating layer 160 is formed on the entire surface of the gate insulating layer 140 and the gate electrode 150. The interlayer insulating layer 160 may be formed of a silicon oxide layer, a silicon nitride layer, or a composite layer thereof.

Subsequently, source and drain contact holes are formed through the gate insulating layer 140 and the interlayer insulating layer 160 to expose the source and drain regions 130a of the semiconductor layer pattern 130, respectively. Source and drain conductive layers are then formed over the interlayer insulating layer 160 and in the source and drain contact holes. Then, the source and drain conductive layers are patterned to form source and drain electrodes 171 and 172. The source and drain electrodes 171 and 172 are coupled to the source and drain regions 130a via the contact holes. Accordingly, a thin film transistor 180 is completed.

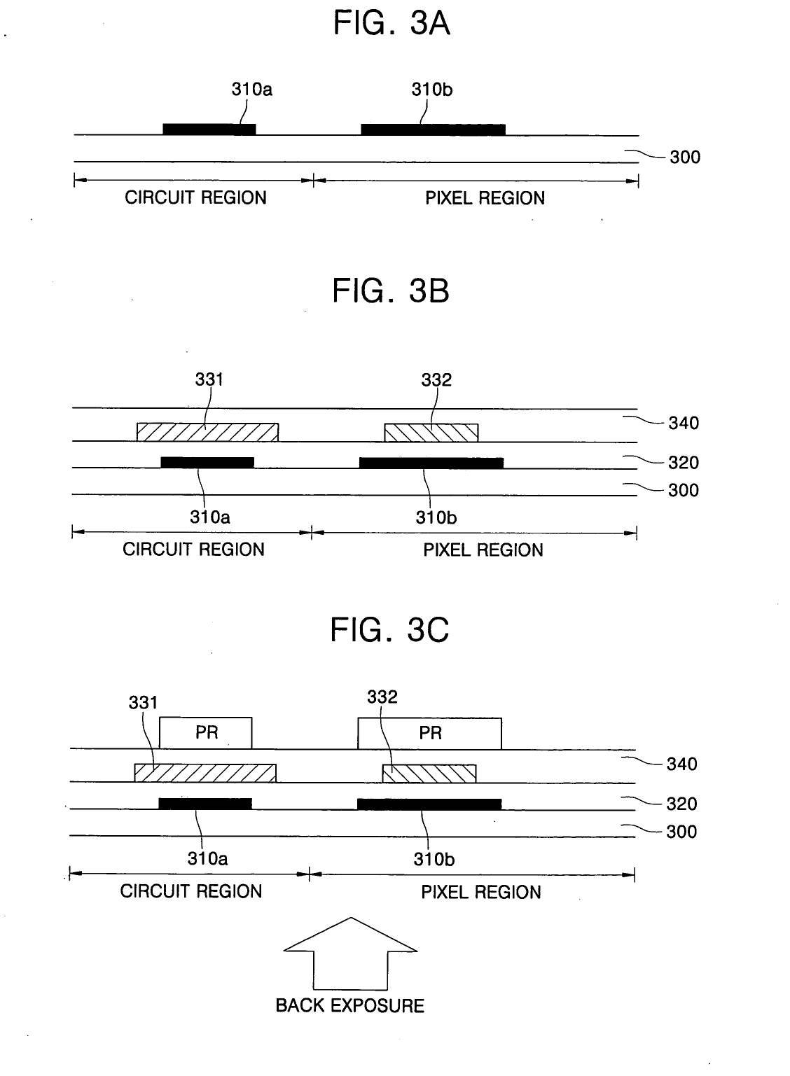

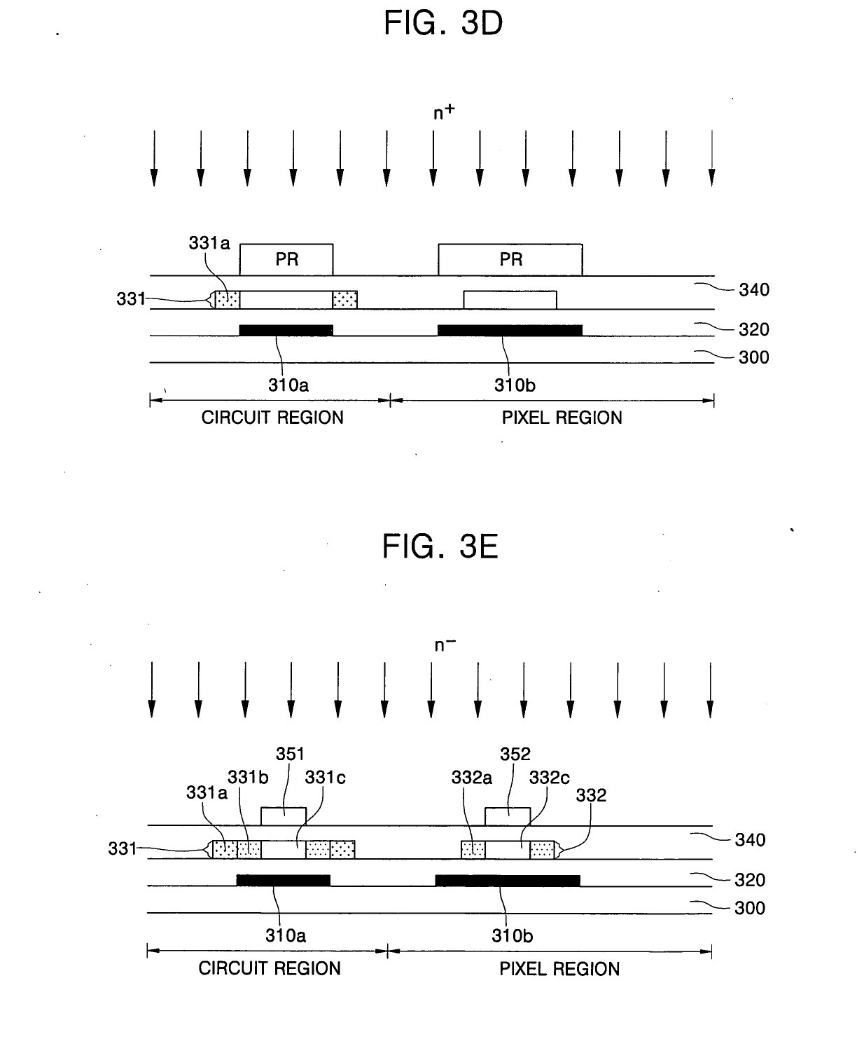

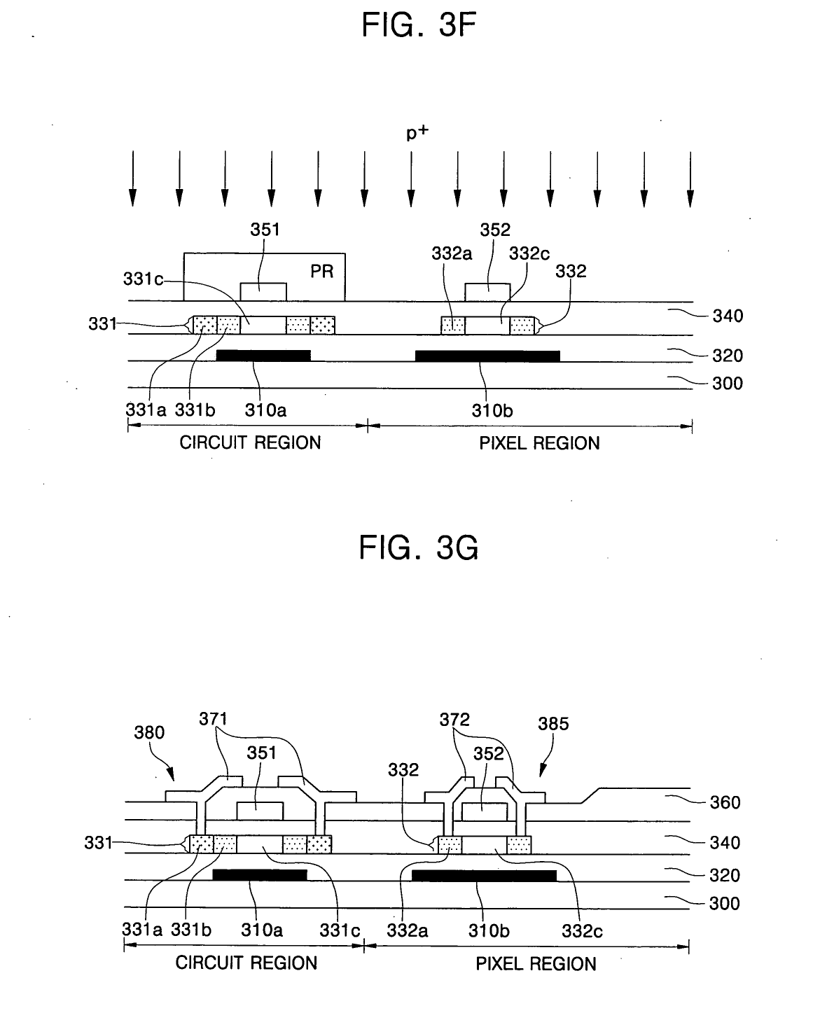

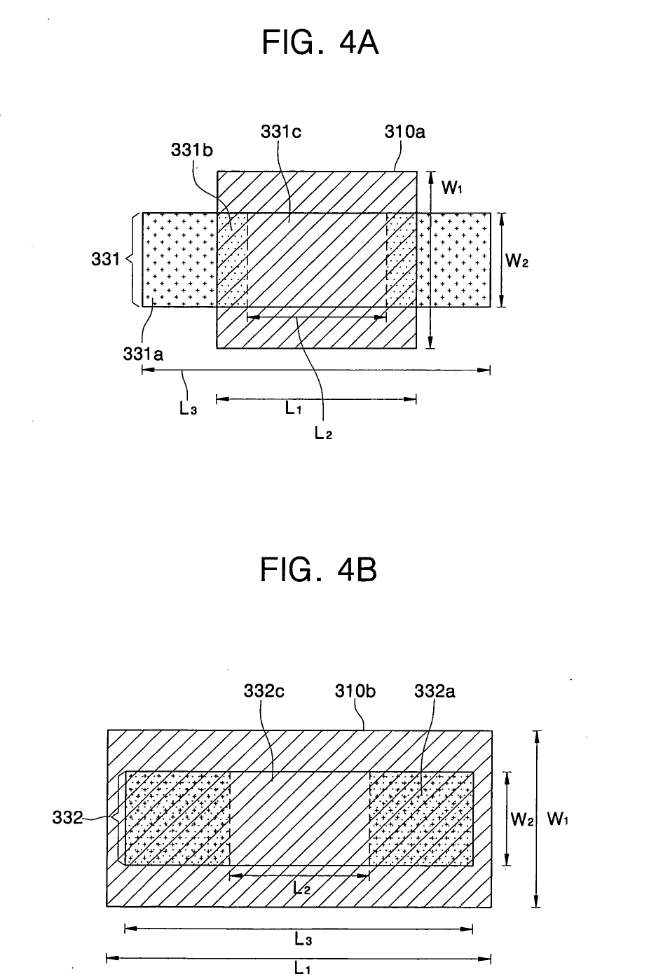

FIGS. 3A to 3G are cross-sectional views illustrating a thin film transistor and a method of fabricating the same in accordance with a second embodiment. FIGS. 4A and 4B are plan views illustrating first and second light-shielding layers and first and second semiconductor layer patterns in a thin film transistor according to the second embodiment.

Referring to FIG. 3A, a substrate 300 including a circuit region and a pixel region is provided. The circuit region includes a first conductive type thin film transistor whereas the pixel region includes a second conductive type thin film transistor. In the illustrated embodiment, the circuit region includes a complementary metal oxide semiconductor (CMOS) transistor serving as a driving circuit element. By a process shown in FIG. 3, N-type thin film transistors of the CMOS transistors may be formed in the circuit region. In addition, a thin film transistor having a conductive type opposite to the first conductive type thin film transistor may be formed in the pixel region. In other embodiments, the pixel region may also include a CMOS transistor and/or an N-type transistor. In certain embodiments, the polarities of the transistors in the circuit and pixel regions may be opposite to those of the illustrated embodiment.

First and second light-shielding layers 310a and 310b are formed in the circuit region and the pixel region of the substrate 300, respectively. The first and second light-shielding layers 310a and 310b may be formed by a photolithographic process followed by an etching process. Each of the first and second light-shielding layers 310a and 310b has an island shape, which is not connected to an electrode which will be described later.

In the illustrated embodiment, widths of the first and second light-shielding layers 310a and 310b are equal to or greater than widths of first and second semiconductor layer patterns. In addition, the length of the first light-shielding layer 310a is greater than the length of the channel region which will be formed in the first semiconductor layer pattern, but is smaller than the length of the first semiconductor layer pattern. The length of the second light-shielding layer 310b is equal to or greater than the length of the second semiconductor layer pattern which will be described later.

Referring to FIG. 4A, the width W1 of the first shielding layer 310a is greater than the width W2 of the first semiconductor layer pattern 331. In addition, the length L1 of the first light-shielding layer 310a is greater than the length L2 of the channel region 331c of the first semiconductor layer pattern 331, but is smaller than the length L3 of the first semiconductor layer pattern 331.

Referring to FIG. 4B, the width W1 of the second light-shielding layer 310b is greater than the width W2 of the second semiconductor layer pattern 332. In addition, it can be seen that the length L1 of the second light-shielding layer 310b is equal to or greater than the length L3 of the second semiconductor layer pattern 332.

As will be described later, the light-shielding layer 310a is formed so as to define a boundary between the source/drain regions 331a and the LDD region 331b . The total length of the LDD regions 331b and the channel region 331c equals to the length L1 of the first light-shielding layer 310a.

The first and second light-shielding layers 310a and 310b formed under the first and second semiconductor layer patterns 331 and 332 block the channel regions 331c and 332c from externally incident lights, and thus prevent light-induced off-current.

Referring to FIG. 3B, a buffer layer 320 is formed on the entire surface of the substrate 300 and the first and second light-shielding layers 310a and 310b. A semiconductor layer is then formed and patterned on the buffer layer 320 to form the first semiconductor layer pattern 331 and the second semiconductor layer pattern 332. A gate insulating layer 340 is then formed on the entire surface of the buffer layer 320 and the first and second semiconductor layers 331 and 332.

Referring to FIG. 3C, a photoresist layer is formed on the gate insulating layer 340. Exposure is then carried out onto a lower surface of the photoresist layer rather than an upper surface of the photoresist layer. In other words, back or upward exposure is carried out to form the photoresist pattern. Development is then carried out to form the photoresist pattern PR.

In the illustrated embodiment, an additional masking step for forming the photoresist pattern PR is not necessary. Instead, the first and second light-shielding layers 310a and 310b serve as masks. In other words, the first and second light-shielding layers 310a and 310b not only protect the channel regions 331c and 332c from externally incident lights but also act as masks. Accordingly, the process can be simplified.

In one embodiment, the width of the photoresist pattern in the circuit region is greater than the width of the first semiconductor layer pattern 331. The length of the photoresist pattern may be shorter than the length of the first semiconductor layer pattern. On the other hand, width and length of the photoresist pattern in the pixel region are greater than width and length of the second semiconductor layer pattern 332.

Referring to FIG. 3D, a high concentration of first impurities is doped in the semiconductor layer pattern 331 using the photoresist pattern as a mask. Accordingly, source and drain regions 331a doped with the first impurities are formed in the first semiconductor layer pattern 331. In the illustrated embodiment, the second semiconductor layer pattern 332 is not doped with the first impurities. The first impurities may be N-type impurities.

Referring to FIG. 3E, the photoresist pattern is removed and a gate conductive layer is formed on the gate insulating layer 340. The gate conductive layer is then patterned to form first and second gate electrodes 351 and 352. The gate electrodes 351 and 352 are configured to cross the first and second semiconductor layer pattern 331 and 332, respectively. In the illustrated embodiment, the first gate electrode 351 has its length shorter than the length of the first light-shielding layer 310a. This configuration allows forming an LDD region in the first semiconductor layer pattern.

Subsequently, a low concentration of the first impurities is doped in the first and second semiconductor layer patterns 331 and 332 using the first and second gate electrodes 351 and 352 as masks. In the illustrated embodiment, the LDD region 331b is formed in the first semiconductor layer pattern 331. At the same time, a channel region 331c is defined to be interposed between the LDD regions 331b under the gate electrode 351. The LDD region, however, is not formed in the second semiconductor layer pattern 332.

The total length of the LDD region 331b and the channel region 331c of the first semiconductor layer pattern 331 equals to the length L1 of the second light-shielding layer 310a. This is consistent with the description relating to formation of the first light-shielding layer 310a of FIG. 4A.

Referring to FIG. 3F, a photoresist pattern is formed on the gate insulating layer 340 of the circuit region including the first gate electrode 351. In the illustrated embodiment, the photoresist pattern is patterned to a size enough to completely cover the first semiconductor layer pattern 331.

A high concentration of second impurities is then doped in the second semiconductor layer pattern 332. In the illustrated embodiment, source and drain regions 332a and a channel region 332c are configured to have a conductive type opposite to that of the first semiconductor layer pattern 331. The regions are formed in the second semiconductor layer pattern 332. The second impurities may be P-type impurities.

Referring to FIG. 3G, an interlayer insulating layer 360 is formed on the entire surface of the gate insulating layer 340 and the first and second gate electrodes 351 and 352. Source and drain contact holes which expose the source and drain regions 331a and 332a of the first and second semiconductor layer patterns 331 and 332 are formed through the gate insulating layer 340 and the interlayer insulating layer 360, respectively.

Subsequently, source and drain conductive layers are formed on the gate insulating layer 340 and in the interlayer insulating layer 360 through the source and drain contact holes. Then, the source and drain conductive layers are patterned to form source and drain electrodes 371 and 372. The source and drain electrodes 371 and 372 are coupled to the source and drain regions 331a and 332a via the contact holes. Accordingly, a first conductive type thin film transistor 380 and a second conductive type thin film transistor 385 are completed. In the illustrated embodiment, the first conductive type thin film transistor is an N-type thin film transistor while the second conductive type thin film transistor is a P-type thin film transistor. Except for the above description, the thin film transistor structure and its fabrication method thereof are the same as those of the first embodiment.

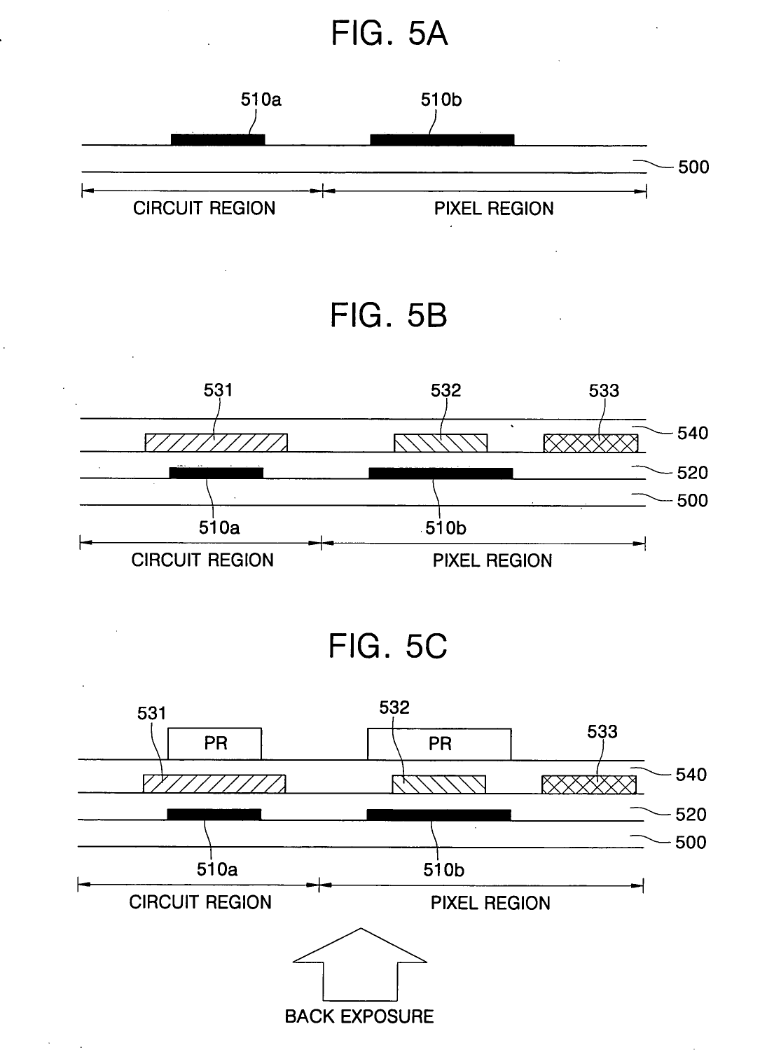

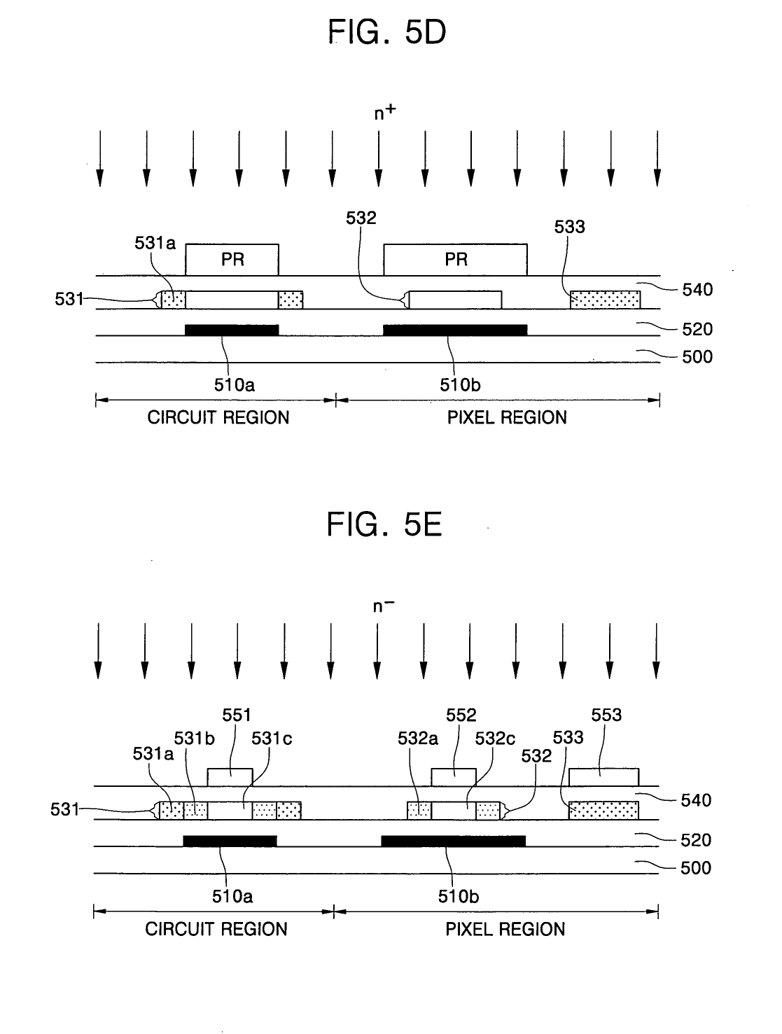

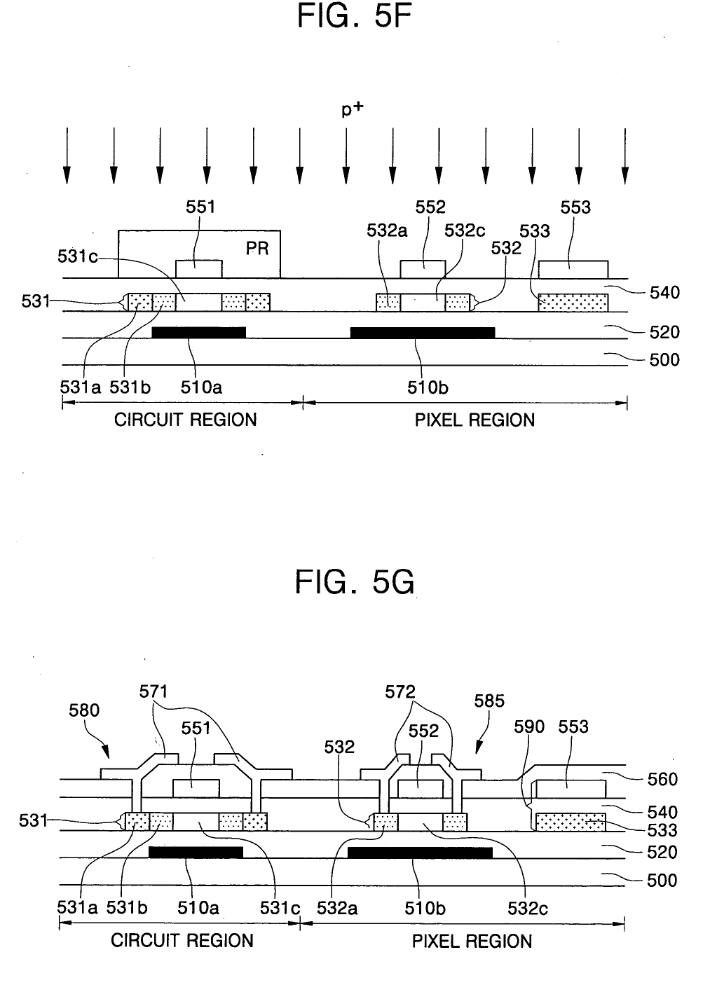

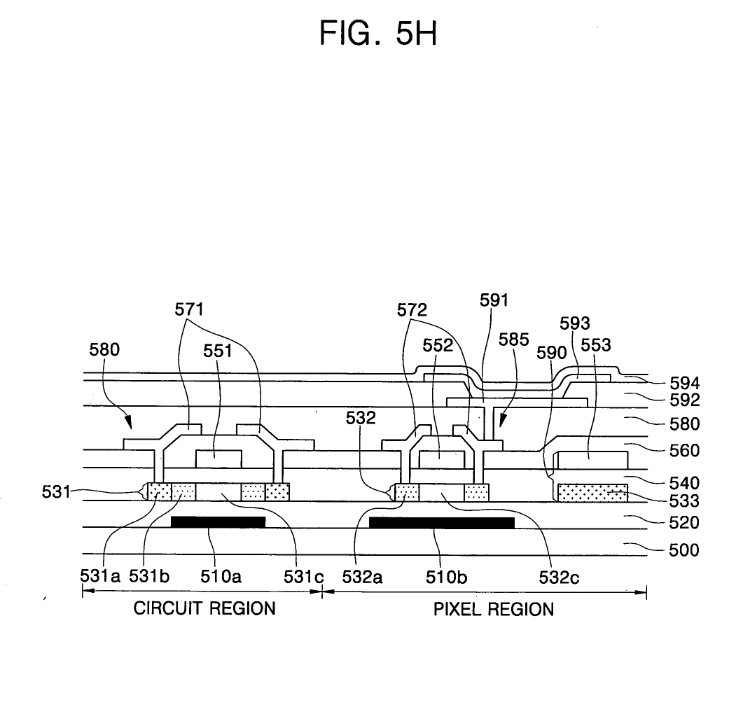

FIGS. 5A to 5H are cross-sectional views illustrating a flat panel display device and a method of fabricating the same in accordance with a third embodiment. The illustrated flat panel display device is an organic light emitting display device. In other embodiments, the flat panel display device includes other types of flat panel display devices including a liquid crystal display device.

Referring to FIG. 5A, a substrate 500 including a circuit region and a pixel region is provided. The circuit region includes a first conductive type thin film transistor whereas the pixel region includes a second conductive type thin film transistor and a capacitor.

In the illustrated embodiment, CMOS transistors serving as driving circuit elements can be formed in the circuit region. N-type thin film transistors of the CMOS transistors may be formed in the circuit region by a process shown in FIG. 5. In addition, a thin film transistor having a conductive type opposite to the first conductive type thin film transistor, and a capacitor are formed in the pixel region.

First and second light-shielding layers 510a and 510b are formed in the circuit region and the pixel region of the substrate 500, respectively. The first and second light-shielding layers 510a and 510b may be formed by a photolithographic process followed by an etching process. Each of the first and second light-shielding layers 510a and 510b has an island shape, which is not connected to an electrode which will be described later.

In the illustrated embodiment, widths of the first and second light-shielding layers 510a and 510b are equal to or greater than widths of first and second semiconductor layer patterns which will be described later. In addition, the length of the first light-shielding layer 510a is greater than the length of the channel region to be formed in the first semiconductor layer pattern, but is smaller than the length of the first semiconductor layer pattern. The length of the second light-shielding layer 510b is equal to or greater than the length of the second semiconductor layer pattern which will be described later.

Referring to FIG. 5B, a buffer layer 520 is formed on the entire surface of the substrate 500 including the first and second light-shielding layers 510a and 510b. A semiconductor layer is then formed and patterned on the buffer layer 520 to form a first semiconductor layer pattern 531, a second semiconductor layer pattern 532, and a bottom electrode 533 of the capacitor.

A gate insulating layer 540 is then formed on the entire surface of the buffer layer 520 including the first and second semiconductor layer patterns 531 and 532 and the bottom electrode 533 of the capacitor.

Referring to FIG. 5C, a photoresist layer is formed on the gate insulating layer 540. Exposure is then carried out in an upward direction on a lower surface of the photoresist layer rather than on an upper surface of the photoresist layer. Development is then carried out to form the photoresist pattern PR. In the illustrated embodiment, an additional masking step for forming the photoresist pattern PR is not necessary because the first and second light-shielding layers 510a and 510b can serve as masks.

A the width of the photoresist pattern formed on the circuit region is greater than the width of the first semiconductor layer pattern 531. The length of the photoresist pattern is shorter than the length of the first semiconductor layer pattern. On the other hand, width and length of the photoresist pattern formed on the pixel region are greater than width and length, respectively, of the second semiconductor layer pattern 532.

Referring to FIG. 5D, a high concentration of first impurities is doped in the semiconductor layer pattern 531 and in the bottom electrode 533 of the capacitor using the photoresist pattern as a mask. Accordingly, source and drain regions 531a doped with the first impurities are formed in the first semiconductor layer pattern 531. In addition, the first impurities are also doped in the bottom electrode 533 of the capacitor so that the bottom electrode has a conductivity. In the illustrated embodiment, the first high concentration impurities are not doped in the second semiconductor layer pattern 532. The first impurities may be N-type impurities.

Referring to FIG. 5E, the photoresist pattern is removed and a gate conductive layer is formed on the gate insulating layer 540. The gate conductive layer is then patterned to form first and second gate electrodes 551 and 552. The gate conductive layer is also patterned to form a top electrode of the capacitor. In this manner, a capacitor 590 is formed in the pixel region.

In the illustrated embodiment, the first gate electrode 551 has a length shorter than the length of the first light-shielding layer 510a. This configuration allows forming an LDD region in the first semiconductor layer pattern.

Subsequently, a low concentration of first impurities is doped in the first and second semiconductor layer patterns 531 and 532 using the first and second gate electrodes 551 and 552 as masks. The LDD region 531b is formed in the first semiconductor layer pattern 531. At the same time, a channel region 531c is defined to be interposed between the LDD regions 531b under the gate electrode 551. The LDD region, however, is not formed in the second semiconductor layer pattern 532. The total length of the LDD regions 531b and the channel region 531c of the first semiconductor layer pattern 531 equals to the length of the second light-shielding layer 510a.

Referring to FIG. 5F, a photoresist pattern is formed on the gate insulating layer 540 of the circuit region including the first gate electrode 551. The photoresist pattern is sized enough to completely cover the first semiconductor layer pattern 531.

A high concentration of second impurities is then doped in the second semiconductor layer pattern 532. Source and drain regions 532a and the channel region 532c having a conductive type opposite to that of the first semiconductor layer pattern 531 are formed in the second semiconductor layer pattern 532. The second impurities may be P-type impurities.

Referring to FIG. 5G, an interlayer insulating layer 560 is formed on the entire surface of the gate insulating layer 540 and the first and second gate electrodes 551 and 552. Source and drain contact holes which expose the source and drain regions 531a and 532a of the first and second semiconductor layer patterns 531 and 532 are formed through the gate insulating layer 540 and the interlayer insulating layer 560.

Subsequently, source and drain conductive layers are formed on the gate insulating layer 540 and in the interlayer insulating layer 560 through the source and drain contact holes. Then, the source and drain conductive layers are patterned to form source and drain electrodes 571 and 572. The source and drain electrodes 571 and 572 are coupled to the source and drain regions 531a and 532a via the contact holes. A first conductive type thin film transistor 580 and a second conductive type thin film transistor 585 are thus completed. In the illustrated embodiment, the first conductive type thin film transistor is an N-type thin film transistor whereas the second conductive type thin film transistor is a P-type thin film transistor. Except for the above description, the thin film transistor structure and the fabrication method thereof are the same as those of the first embodiment.

Referring to FIG. 5H, a planarization layer 580 is formed on the interlayer insulating layer 560 including the source and drain electrodes 571 and 572 of the first and second conductive type thin film transistors. The planarization layer 580 may be formed of an organic layer, an inorganic layer, or a composite layer thereof. The organic layer may be a benzocyclobutene (BCB) layer. The inorganic layer may be a silicon oxide layer or a silicon nitride layer.

In addition, a via hole is formed in the planarization layer 580 which exposes one of the source and drain electrodes 572 of the second conductive type thin film transistor 585. The via hole is configured to expose the drain electrode in the illustrated embodiment.

A pixel electrode material is then formed on the planarization layer 580 through the via hole. The material is then patterned to form a pixel electrode 591. The pixel electrode 591 may be formed of a transparent conductive material. In this manner, a bottom emission type organic light emitting diode can be fabricated. The transparent conductive material may be indium tin oxide (ITO) or indium zinc oxide (IZO).

Subsequently, a pixel defining layer 592 is formed on the pixel electrode 591. The pixel defining layer 592 is configured to expose a predetermined portion of a surface of the pixel electrode 591. The pixel defining layer 592 may be formed of a material selected from BCB, an acrylic polymer and an imide based polymer.

An organic layer pattern 593 having at least an organic light-emitting layer is formed on the exposed pixel electrode 591. A counter electrode 594 is formed on the organic layer pattern 593. The counter electrode 594 may be formed of a reflective material. The pixel electrode 591, the organic layer pattern 593, and the counter electrode 594 may constitute an organic light emitting diode. A process of encapsulating the organic light emitting diode is then carried out to complete the organic light emitting display device.

The embodiments described above provide thin film transistors and the methods of fabricating the same which can prevent light-induced off-current using the light-shielding layer. In addition, the light-shielding layer formed below the N-type thin film transistor blocks light from reaching the semiconductor layer except for the high concentration N-type regions. Thus, high concentration impurities can be doped without an additional masking step. In addition, the configuration of the thin film transistor allows a flat panel display device to have an improved image quality.

Although the present invention has been described with reference to certain exemplary embodiments thereof, changes may be made to the described embodiments without departing from the scope of the present invention.

What is claimed:

1. A flat panel display device, comprising:
a substrate having a surface;
a display array formed over the surface, the display array comprising a plurality of pixels;
a transistor formed over the surface and comprising a gate, a semiconductor layer, and a gate insulating layer interposed between the gate and the semiconductor layer, the semiconductor layer comprising a source, a drain, a channel, a first lightly-doped region located between the source and the channel, and a second lightly-doped region located between the drain and the channel; and
means for selectively blocking light so as to form a mask for use in doping the source and drain regions of the semiconductor layer during fabrication of the transistor, the means being interposed between the surface and the semiconductor layer.

2. The device of claim 1, wherein the source and the first lightly-doped region form a first boundary therebetween by a substantially discrete differential in the concentration of a dopant at both sides of the first boundary, wherein the drain and the second lightly-doped region form a second boundary therebetween by a substantially discrete differential in the concentration of the dopant at both sides of the second boundary, and wherein the location and size of the means determines the location of the first and second boundaries.

3. The device of claim 2, wherein the channel has a channel length in a first axis and a channel width in a second axis perpendicular to the first axis, the first and second axes being substantially parallel to the surface, wherein the first and second boundaries extend in the second axis, wherein the means comprises a light-shielding layer having a first edge and second edge, both extending generally in the second axis, and wherein the first edge underlies the first boundary and the second edge underlies the second boundary.

4. The device of claim 3, wherein the light-shielding layer has the width in the second axis, and wherein the width of the light-shielding layer is about equal to or greater than the channel width.

5. The device of claim 3, wherein the first edge substantially directly underlies the first boundary, and wherein the second edge substantially directly underlies the second boundary.

6. The device of claim 3, wherein the light-shielding layer has the length in the first axis, and wherein the length of the light-shielding layer is substantially equal to a total length of the channel and the first and second lightly-doped regions.

7. The device of claim 3, wherein the gate has a first gate edge and second gate edge, both extending generally in the second axis, wherein the first gate edge overlies a boundary between the first lightly-doped region and the channel, and wherein the second gate edge overlies a boundary between the second lightly-doped region and the channel.

8. The flat panel display device of claim 2, wherein the first and second boundaries further extend in a general direction perpendicular to the surface with or without a slight bending along the first axis.

9. The device of claim 1, wherein the transistor is located between the substrate and the display array.

10. The device of claim 1, wherein each of the plurality of pixels comprises an organic light emitting diode.

11. The device of claim 1, wherein the light-shielding layer comprises a metal.

12. The device of claim 1, further comprising a buffer layer interposed between the light-shielding layer and the semiconductor layer, wherein the buffer layer blocks migration of materials between the light-shielding layer and the semiconductor layer.

13. A method of making a flat panel display device, comprising:
providing a transparent substrate;
forming a light-shielding layer over the substrate;
forming a semiconductor layer over the light-shielding layer;
forming a photoresist layer over the semiconductor layer;
projecting light in a direction such that the light passes through the substrate before reaching the photoresist layer, wherein the light-shielding layer blocks the light, and wherein the light selectively illuminates at least one portion of the photoresist layer; and
removing the at least one illuminated portion of the photoresist layer while leaving at least one non-illuminated portion.

14. The method of claim 13, wherein removing the at least one illuminated portion comprises forming a doping mask over the semiconductor layer while exposing at least one portion of the semiconductor layer.

15. The method of claim 14, further comprising selectively doping with a dopant the at least one portion of the semiconductor layer using the doping mask, thereby forming a source and a drain in the semiconductor layer.

16. The method of claim 13, further comprising, prior to forming the semiconductor layer, forming a buffer layer over the light-shielding layer so as to prevent migration of materials between the light-shielding layer and the semiconductor layer.

17. The method of claim 13, further comprising, prior to forming the photoresist layer, forming a gate insulating layer over the semiconductor layer.

18. The method of claim 17, further comprising:
removing the photoresist layer;
forming a gate electrode over the gate insulating layer; and
selectively doping with a dopant one or more portions of the semiconductor layer using the gate electrode as a mask, thereby creating one or more lightly-doped drain regions in the semiconductor layer.

19. The method of claim 18, wherein the one or more lightly-doped drain regions comprise a first lightly-doped drain region and a second lightly-doped drain region, and wherein the semiconductor layer comprises a channel between the first and second lightly-doped regions, the channel having a channel width and a channel length.

20. The method of claim 19, wherein the light-shielding layer has the length in the direction of the channel length, and wherein the length of the light-shielding layer is substantially equal to the total length of the channel and the first and second lightly-doped regions.

21. The method of claim 13, wherein the semiconductor layer comprises a channel of a transistor, the channel comprising a channel width and a channel length, wherein the light-shielding layer has the width in the direction of the channel width, wherein the width of the light-shielding layer is about equal to or greater than the channel width.

22. A flat panel display device made by the method of claim 13.
